(19) United States
(12) Patent Application Publication
(10) Pub. No.: US 2025/0089477 A1
(43) Pub. Date: Mar. 13, 2025

(54) DISPLAY DEVICE

(71) Applicant: Samsung Display Co., LTD., Yongin-si (KR)

(72) Inventor: OHJUNE KWON, Yongin-si (KR)

(21) Appl. No.: 18/746,414

(22) Filed: Jun. 18, 2024

(30) Foreign Application Priority Data
Sep. 11, 2023 (KR) 10-2023-0120084

(51) Int. Cl. H10K 59/124; G06F 3/041; H10K 59/80

(52) U.S. Cl. CPC H10K 59/124; H10K 59/873; G06F 3/0412

(57) ABSTRACT

A display device includes: a substrate including a main display area and a component area adjacent to the main display area, a light emitting element layer disposed in the main display area and the component area on the substrate and including at least one light emitting element, an inorganic layer disposed on the light emitting element layer, a planarization member disposed in the component area on the inorganic layer and having a surface energy different from a surface energy of the inorganic layer, and an organic layer disposed on the inorganic layer and the planarization member.

This application claims priority to Korean Patent Application No. 10-2023-0120084, filed on Sep. 11, 2023, and all the benefits accruing therefrom under 35 U.S.C. § 119, the content of which in its entirety is herein incorporated by reference.

### BACKGROUND

### 1. Field

Embodiments relate to a display device. More particularly, the embodiments relate to the display device with a component area.

### 2. Description of the Related Art

The display device is a device that displays an image for providing visual information to a user. Recently, a thickness of the display device has become thinner and a weight of the display device has become lighter, and the scope of a usage of the display device has expanded.

As an area occupied by a display area of the display device is expanded, various functions are being added to the display area. For example, the display device may include a component area that performs various functions while displaying the image.

### SUMMARY

Embodiments provide a display device with an improved display quality.

A display device according to an embodiment may include a substrate including a main display area and a component area adjacent to the main display area, a light emitting element layer disposed in the main display area and the component area on the substrate and including at least one light emitting element, an inorganic layer disposed on the light emitting element layer, a planarization member disposed in the component area on the inorganic layer and having a surface energy different from a surface energy of the inorganic layer, and an organic layer disposed on the inorganic layer and the planarization member.

In an embodiment, the inorganic layer may have a step portion in the component area and the planarization member is arranged to overlap the step portion.

In an embodiment, the surface energy of the planarization member may be lower than the surface energy of the inorganic layer.

In an embodiment, the planarization member may include an inorganic material.

In an embodiment, the component area may include a transmission area that an external light passes through and a non-transmission area adjacent to the transmission area.

In an embodiment, the planarization member may be disposed in the transmission area and the non-transmission area in a plan view.

In an embodiment, the planarization member may transmit at least a portion of an incident light.

In an embodiment, the inorganic layer may be an inorganic encapsulation layer that covers the light emitting element and the organic layer may be an organic encapsulation layer disposed on the inorganic encapsulation layer.

In an embodiment, the display device may further include an encapsulation layer disposed between the inorganic layer and the light emitting element layer and a touch electrode disposed between the inorganic layer and the organic layer.

In an embodiment, an upper surface of the organic layer may be substantially flat over the component area and at least a portion of the main display area adjacent to the component area.

A display device according to an embodiment may include a substrate including a main display area and a component area adjacent to the main display area, a light emitting element layer disposed in the main display area and the component area on the substrate and including at least one light emitting element, an inorganic layer disposed on the light emitting element layer, a planarization member disposed in the component area on the inorganic layer and having a surface energy different from a surface energy of the inorganic layer, and an organic layer disposed on the inorganic layer and the planarization member and including an upper surface with a concave-convex structure including a concave portion and a convex portion.

In an embodiment, the inorganic layer may have a step portion in the component area and the planarization member is arranged to overlap the step portion.

In an embodiment, the surface energy of the planarization member may be lower than the surface energy of the inorganic layer.

In an embodiment, the planarization member may include an inorganic material.

In an embodiment, the convex portion may be located to correspond to a location that the planarization member is disposed in a plan view.

In an embodiment, the planarization member may transmit at least a portion of an incident light.

In an embodiment, the component area may include a transmission area that an external light passes through and a non-transmission area adjacent to the transmission area.

In an embodiment, the planarization member may be disposed in the transmission area in a plan view.

In an embodiment, the inorganic layer may be an inorganic encapsulation layer that covers the light emitting element and the organic layer may be an organic encapsulation layer disposed on the inorganic encapsulation layer.

In an embodiment, the display device may further include an encapsulation layer disposed between the inorganic layer and the light emitting element layer and a touch electrode disposed between the inorganic layer and the organic layer.

In a display device according to embodiments of the present disclosure, the display device may include an inorganic layer disposed on a light emitting element layer, an organic layer disposed on the inorganic layer, and a planarization member disposed between the inorganic layer and the organic layer. A surface energy of the planarization member may be lower than a surface energy of the inorganic layer. Accordingly, the organic layer may have a substantially flat surface over a component area and a main display area through the planarization member.

In addition, as the planarization member may have a circular ring shape in a plan view, the organic layer may have a concave-convex structure including a concave portion and a convex portion. Accordingly, when an incident light from outside passes through the component area, a condensation of the light may be improved. In addition, a characteristic of image quality in the component area of the display device may be further improved.

### BRIEF DESCRIPTION OF THE DRAWINGS

Illustrative, non-limiting embodiments will be more clearly understood from the following detailed description in conjunction with the accompanying drawings.

FIG. 1 is a plan view illustrating a display device according to an embodiment of the present disclosure.

FIG. 2 is an enlarged plan view illustrating a component area in FIG. 1.

FIG. 3 is a cross-sectional view illustrating an example taken along line I-I′ in FIG. 1.

FIG. 4 is an enlarged plan view illustrating an area A1 in FIG. 3.

FIG. 5 is a cross-sectional view illustrating another example taken along line I-I′ in FIG. 1.

FIG. 6 is a plan view illustrating a display device according to another embodiment of the present disclosure.

FIG. 7 is a cross-sectional view illustrating an example taken along line II-II′ in FIG. 6.

FIG. 8 is an enlarged plan view illustrating an area A2 in FIG. 7.

FIG. 9 is a plan view illustrating a component area in FIG. 7.

FIG. 10 is a perspective view illustrating an organic layer disposed in a component area.

FIG. 11 is a cross-sectional view illustrating another example taken along line II-II′ in FIG. 6.

### DETAILED DESCRIPTION

The terminology used herein is for the purpose of describing particular embodiments only and is not intended to be limiting. As used herein, “a”, “an,” “the,” and “at least one” do not denote a limitation of quantity, and are intended to include both the singular and plural, unless the context clearly indicates otherwise. For example, “an element” has the same meaning as “at least one element,” unless the context clearly indicates otherwise. “At least one” is not to be construed as limiting “a” or “an.” “Or” means “and/or.” As used herein, the term “and/or” includes any and all combinations of one or more of the associated listed items. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

It will be understood that when an element is referred to as being “on” another element or “connected to” another element, it can be directly on or directly connected to the other element or intervening elements may be present therebetween. In contrast, when an element is referred to as being “directly on” another element, there are no intervening elements present. Hereinafter, display devices in accordance with embodiments will be described in more detail with reference to the accompanying drawings. The same reference numerals are used for the same components in the drawings, and redundant descriptions of the same components will be omitted.

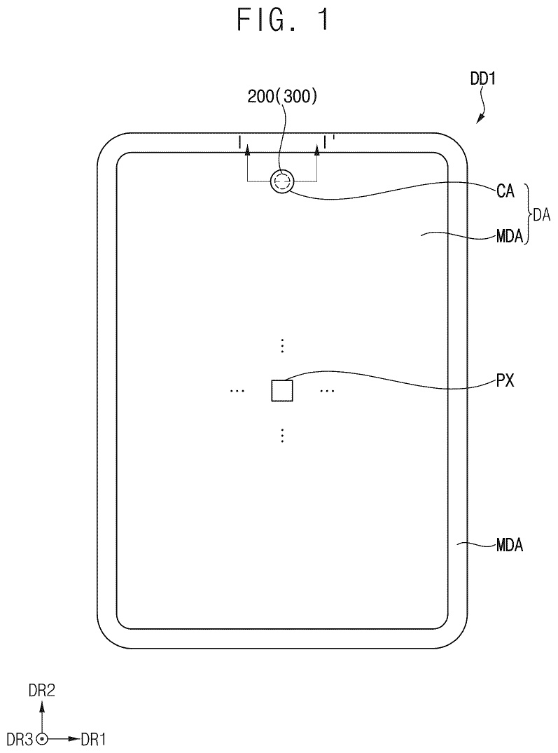

FIG. 1 is a plan view illustrating a display device according to an embodiment of the present disclosure. As used herein, the “plan view” is a view in a thickness direction (i.e., third direction DR3) of the substrate SUB.

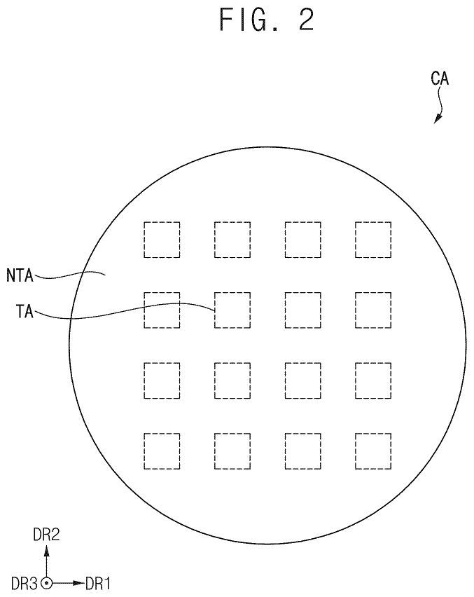

Referring to FIG. 1, a display device DD1 according to an embodiment (e.g., a substrate SUB in FIG. 2) may include a display area DA and non-display area NDA. A display area DA may include a component area CA and a main display area MDA surrounding at least portion of the component area CA.

The main display area MDA may be defined as an area that displays an image by generating a light or adjusting a transmittance of light provided from an external light source. At least one pixel PX may be disposed in the main display area MDA. The pixel PX may emit light. The pixel PX may be repeatedly arranged along a first direction DR1 and a second direction DR2 intersecting the first direction DR1. In addition, the pixel PX may include a plurality of sub-pixels that emit light of different colors. For example, the sub-pixels may include a red sub-pixel that emits red light, a green sub-pixel that emits green light, and a blue western pixel that emits blue light.

The component area CA may be disposed in the display area DA. In an embodiment, the component area CA may be disposed in an upper center of the display area DA. In an embodiment, the component area CA may be disposed in an upper left corner of the display area DA. In an embodiment, the component area CA may be disposed in an upper right corner of the display area DA.

In an embodiment, the component area CA may have a circular shape in a plan view. In an embodiment the component area CA may have a shape different from the circular shape. For example, the component area CA may have a polygonal shape in a plan view.

At least on pixel PX that can emits light may be also disposed in the component area CA. The pixel PX may be repeatedly arranged along the first direction DR1 and the second direction DR2.

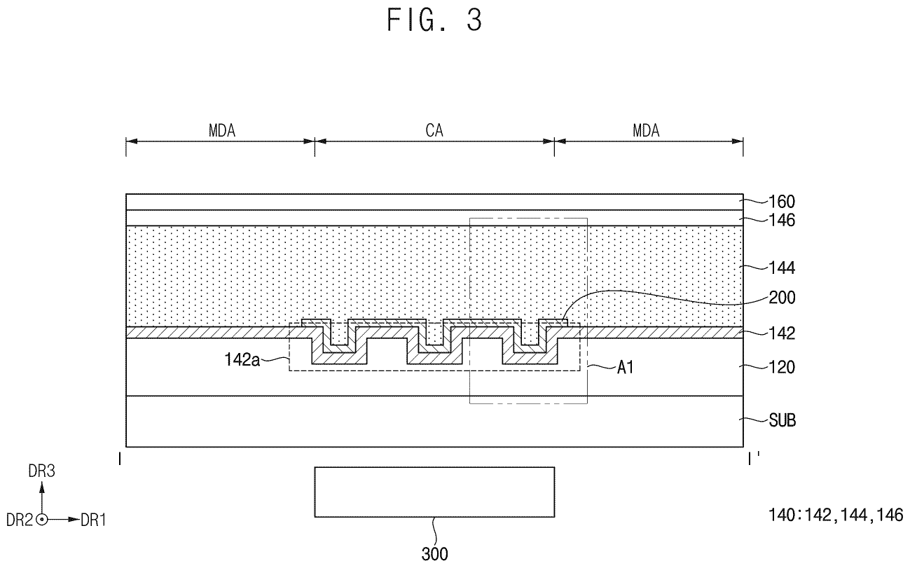

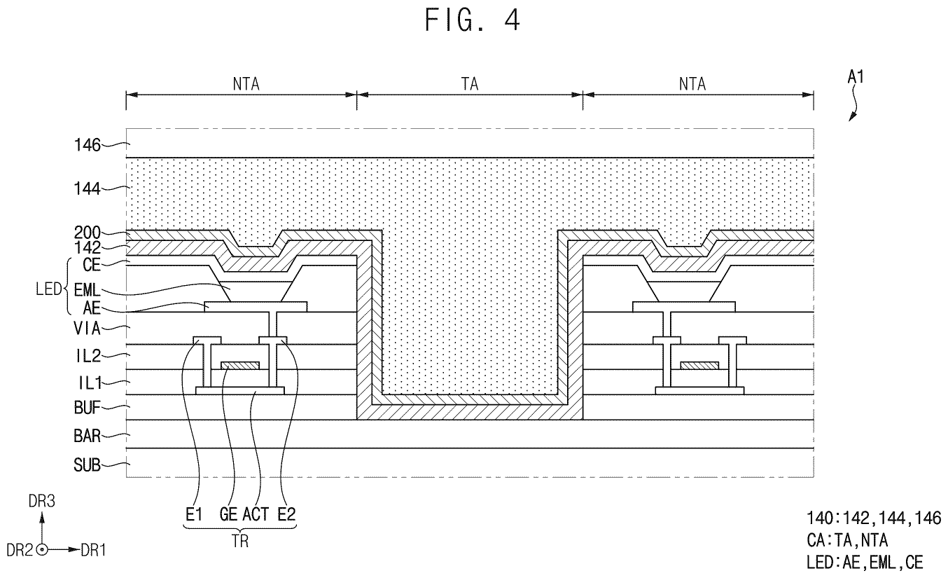

A component 300 may be disposed under the substrate (e.g., the substrate SUB in FIG. 2) corresponding to the component area CA in a plan view. The component 300 may receive a light transmitting the component area CA. An explanation about the component 300 will be explained later with reference to FIGS. 3 and 4.

The non-display area NDA may be located around the display area DA. In an embodiment, for example, the non-display area NDA may surround at least a portion of the display area DA. A driver may be disposed in the non-display area NDA. In an embodiment, for example, the driver may include a data driver, a gate driver, and/or the like.

The non-display area NDA may not display an image. Meanwhile, the present disclosure may not be limited to this, and the image may be displayed in at least a portion of the non-display area NDA in another embodiment.

FIG. 2 is an enlarged plan view illustrating a component area in FIG. 1.

Referring to the FIG. 2, the component area CA may include a transmission area TA and non-transmission area NTA. The non-transmission area NTA may be adjacent to the transmission area TA.

The transmission area TA may be disposed by repeatedly arranging along the first direction DR1 and the second direction DR2 in a plan view. In addition, the non-transmission area NTA may be an area among two adjacent transmission areas TA. In an embodiment, the transmission area TA may be an area that light is transmitted. In an embodiment, for example, the transmission area TA may be an area where a metal material (e.g., a pixel electrode AE) is not disposed. In addition, the non-transmission area NTA may an area where the metal material is disposed. Accordingly, an arrangement relationship and an area of the transmission area TA and the non-transmission area NTA may vary depending on a shape of the metal material.

FIG. 3 is a cross-sectional view illustrating an example taken along line I-I′ in FIG. 1. FIG. 4 is an enlarged plan view illustrating an area A1 in FIG. 3.

Referring to FIGS. 3 and 4, the display device DD1 may include the substrate SUB, a barrier layer BAR, a buffer layer BUF, an active pattern ACT, a first insulating layer IL1, a gate electrode GE, a second insulating layer IL2, a first electrode E1, a second electrode E2, an organic insulating layer VIA, the pixel electrode AE, an light emitting layer EML, a pixel defining layer PDL, a common electrode CE, an encapsulation layer 140, a touch layer 160, a planarization member 200, and a component 300.

The substrate SUB may include a transparent material or an opaque material. The substrate SUB may include a transparent resin substrate. In an embodiment, for example, the transparent resin substrate may include a polyimide substrate.

Alternatively, the substrate SUB may include a quartz substrate, a synthetic quartz substrate, a calcium fluoride substrate, a fluorine-doped quartz substrate, a soda lime glass substrate, a non-alkali glass substrate, and/or the like. These may be used alone or in combination with each other.

The barrier layer BAR may be disposed on the substrate SUB. The barrier layer BAR may prevent impurities from penetrating into an upper portion of the substrate SUB from an outside. The barrier layer BAR may include an inorganic material. In an embodiment, for example, the inorganic material may include a silicon oxide (SiOx), silicon nitride (SiNx), silicon oxynitride (SiNxOy), and the like. These may be used alone or in combination with each other.

The barrier layer BAR may be formed as a single-layer structure or a multi-layer structure. The barrier layer BAR may be continuously disposed across the main display area MDA, the non-transmission area NTA, and the transmission area TA.

The buffer layer BUF may be disposed on the barrier layer BAR. The buffer layer BUF may prevent metal atoms or impurities from spreading to active pattern ACT. The buffer layer BUF may be disposed in the main display area MDA and the non-transmission area NTA. That is, the buffer layer BUF may not be disposed in the transmission area TA.

In an embodiment, the buffer layer may include an inorganic material. In an embodiment, for example, the inorganic material may include a silicon oxide, a silicon nitride, a silicon oxynitride, and/or the like. These may be used alone or in combination with each other.

The first insulating layer IL1 may be disposed on the buffer layer BUF. The first insulating layer IL1 may cover the active pattern ACT. The first insulating layer IL1 may include an inorganic material. The first insulating layer IL1 may be disposed in the main display area MDA and the non-transmission area NTA. That is, The first insulating layer IL1 may not be disposed in the transmission area TA.

The gate electrode GE may be disposed on the first insulating layer IL1. The gate electrode GE may overlap a channel area of the active pattern ACT in a plan view. The gate electrode GE may include a metal, an alloy, a conductive metal oxide, a conductive metal nitride, a transparent conductive material, and/or the like. The gate electrode GE may be disposed in the main display area MDA and the non-transmission area NTA. That is, the gate electrode GE may not be disposed in the transmission area TA.

The second insulating layer IL2 may be disposed on the first insulating layer IL1. The second insulating layer IL2 may cover the gate electrode GE. The second insulating layer IL2 may include an inorganic material. The second insulating layer IL2 may be disposed in the main display area MDA and the non-transmission area NTA. That is, the second insulating layer IL2 may not be disposed in the transmission area TA.

The first electrode E1 and the second electrode E2 may be disposed on the second insulating layer IL2. The first electrode E1 and the second electrode E2 may contact a source area and a drain area of the active pattern ACT through a contact hole which penetrates the first insulating layer IL1 and the second insulating layer IL2. The first electrode E1 and the second electrode E2 may include a metal, an alloy, a conductive a metal oxide, a conductive metal nitride, a transparent conductive material, and/or the like. The active pattern ACT, the gate electrode GE, the first electrode E1, and the second electrode E2 may form a transistor TR. The first electrode E1 and the second electrode E2 may be disposed in the main display area MDA and the non-transmission area NTA. That is, the first electrode E1 and the second electrode E2 may not be disposed in the transmission area TA.

The organic insulating layer VIA may be disposed on the second insulating layer IL2. The organic insulating layer VIA may cover the first electrode E1 and the second electrode E2. The organic insulating layer VIA may include an organic insulating material. In an embodiment, for example, the organic insulating material may include a phenolic resin, a polyacrylates resin, a polyimides resin, a polyamides resin, a siloxane resin, an epoxy resin, and/or the like. These may be used alone or in combination with each other. The organic insulating layer VIA may be disposed in the main display area MDA and the non-transmission area NTA. That is, the organic insulating layer VIA may not be disposed in the transmission area TA.

The pixel electrode AE may be disposed on the organic insulating layer VIA. The pixel electrode AE may contact the first electrode E1 and the second electrode E2 through a contact hole which penetrates the organic insulating layer VIA. Accordingly, the pixel electrode AE may connect with the transistor TR electrically. The pixel electrode AE may be disposed in the main display area MDA and the non-transmission area NTA. That is, the pixel electrode AE may not be disposed in the transmission area TA.

The pixel defining layer PDL may be disposed on the organic insulating layer VIA. The a pixel defining layer PDL may cover the pixel electrode AE partially on the organic insulating layer VIA. The a pixel defining layer PDL may define a pixel opening exposing at least a portion of an upper surface of the pixel electrode AE. The pixel defining layer PDL may be disposed in the main display area MDA and the non-transmission area NTA. That is, pixel defining layer PDL may not be disposed in the transmission area TA.

In an embodiment, the pixel defining layer PDL may include a inorganic material or an organic material. In an embodiment, for example, the organic material may include an epoxy resin, a siloxane resin, and/or the like. These may be used alone or in combination with each other. In an embodiment, the pixel defining layer PDL may further include a light-blocking material including a black pigment, a black dye, and/or the like.

The light emitting layer EML may be disposed on the pixel electrode AE. In an embodiment, for example, the light emitting layer EML may be disposed on the pixel electrode AE exposed from the pixel defining layer PDL. In an embodiment, the light emitting layer EML may have a multilayer structure including a hole injection layer, a hole transport layer, an organic light emitting layer, an electron transport layer, an electron injection layer and/or the like. The light emitting layer EML may disposed in the main display area MDA and the non-transmission area NTA.

The common electrode CE may disposed on the light emitting layer EML and the pixel defining layer PDL. The light emitting layer EML may emit light based on a voltage difference between the pixel electrode AE and the common electrode CE. The common electrode CE may be disposed in the main display area MDA and the non-transmission area NTA. The pixel electrode AE, the light emitting layer EML, and the common electrode CE may form a light emitting diode LED. In addition, a light emitting element layer 120 may include at least one light emitting diode LED.

The encapsulation layer 140 may include at least one inorganic encapsulation layer and one of a organic encapsulation layer. In an embodiment, for example, the encapsulation layer 140 may include a first inorganic encapsulation layer 142, and a second inorganic encapsulation layer 146 disposed on the first inorganic encapsulation layer 142, and an organic encapsulation layer 144 disposed between the first inorganic encapsulation layer 142 and the second inorganic encapsulation layer 146. The encapsulation layer 140 may reduce a formation of a path through which moisture or oxygen from outside penetrates into the light emitting element layer 120.

The first inorganic encapsulation layer 142 may disposed on the common electrode CE. In an embodiment, for example, the first inorganic encapsulation layer 142 may cover an upper portion of the light emitting element layer 120 over the transmission area TA, the non-transmission area NTA and the main display area MDA. The first inorganic encapsulation layer 142 may include an inorganic material. In an embodiment, for example, the inorganic material may include a silicon nitride, a silicon oxide, a silicon oxynitride, and/or the like. These may be used alone or in combination with each other. In this specification, the first inorganic encapsulation layer 142 may be referred to as an “inorganic layer”.

In FIG. 4, it may be shown that all configurations of an upper portion of the barrier layer BAR and a lower portion of the first inorganic encapsulation layer 142 is not disposed in the transmission area TA, but the present disclosure may not be limited to this. For another example, in the transmission area TA, among various configurations disposed on the substrate, at least one of the configurations excluding a configuration that reflects light may be disposed

As at least one of configurations of the light emitting element layer 120 disposed in the non-transmission area NTA is not disposed in the transmission area TA, an upper surface of the light emitting element layer 120 in the component area CA may have a step. Accordingly, as shown in FIG. 3, the first inorganic encapsulation layer 142 disposed on the light emitting element layer 120 may have a step portion 142a in the component area CA.

The planarization member 200 may be disposed on the first inorganic encapsulation layer 142. In an embodiment, for example, the planarization member 200 may disposed in all of the component area CA and a portion of the main display area adjacent to the component area CA. Specifically, a portion of the planarization member 200 may not be removed from the main display area MDA during the process, and the portion of the planarization member 200 may be disposed in a portion of the main display area MDA adjacent to the component area CA.

In an embodiment, the planarization member 200 may be disposed to overlap the step portion 142a in a plan view. Accordingly, the planarization member 200 may compensate a step of the step portion 142a of the first inorganic encapsulation layer 142.

The planarization member 200 may have a surface energy different from a surface energy of the first inorganic encapsulation layer 142. In an embodiment, the surface energy of the planarization member 200 may be lower than the surface energy of the first inorganic encapsulation layer 142. Accordingly, an organic material forming the organic encapsulation layer 144 may gather in an area where the planarization member 200 is disposed rather than an area where only the first inorganic encapsulation layer 142 is disposed. Accordingly, although a step exists between the transmission layer TA and the non-transmission area NTA (that is, the step portion 142a of the first inorganic encapsulation layer 142), the organic encapsulation layer 144 may have substantially a flat upper surface over the component area CA and the main display area MDA.

In an embodiment, the planarization member 200 may transmit at least a portion of an incident light. Accordingly, the incident light may reach the component 300 by transmitting the planarization member 200.

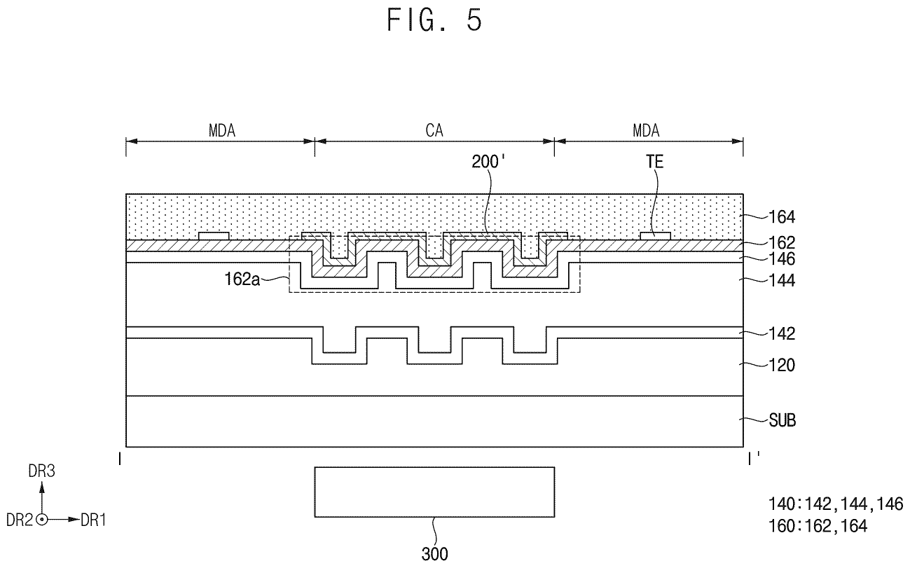

The organic encapsulation layer 144 may be disposed on the first inorganic encapsulation layer 142. The organic encapsulation layer 144 may not from a step around the first inorganic encapsulation layer 142 and as explained in detail previously the organic encapsulation layer 144 may have a substantially flat upper surface. In an embodiment, an upper surface of the organic encapsulation layer 144 may be substantially flat over the component area CA and at least a portion of the main display area adjacent to the component area CA. The flatness of the upper surface of the organic encapsulation layer 144 may be due to the difference of between the surface energy of the planarization member 200 and the surface energy of the first inorganic encapsulation layer 142, as described above. As used herein, “substantially flat” is inclusive of the stated value and means within an acceptable range of deviation for the particular value as determined by one of ordinary skill in the art, considering the measurement in question and the error associated with measurement of the particular quantity (i.e., the limitations of the measurement system). For example, “substantially flat” can mean within one or more standard deviations, or within ±10% or 5% of the step of the step portion (e.g., 142a of the first inorganic encapsulation layer 142 in FIG. 3 or 162a of the first touch insulating layer 162 in FIG. 5).

The organic encapsulation layer 144 may include an organic material. In an embodiment, for example, the organic material may include a polyethylene terephthalate, a polyethylene naphtalate, a polycarbonate, a polyimde, a polyethyelene sulfonate, a polyoxymethylene, a polyarylate, a hexamethyl disiloxane, and/or the like. These may be used alone or in a combination with each other. The organic encapsulation layer 144 may be referred to as an “organic layer”.

The second inorganic encapsulation layer 146 may be disposed on the organic encapsulation layer 144. The second inorganic encapsulation layer 146 may have a substantially uniform thickness and have a substantially flat surface. The second inorganic encapsulation layer 146 may include an inorganic material. In an embodiment, for example, the inorganic material include a silicon nitride, a silicon oxide, a silicon oxynitride, and/or the like. These may be used alone or in a combination with each other.

The touch layer 160 may be disposed on the encapsulation layer 140. In an embodiment, for example, the touch layer 160 may be disposed on the second inorganic encapsulation layer 146. Specifically, the touch layer 160 may be disposed on the second inorganic encapsulation layer 146 over the main display area MDA and the component area CA. The touch layer 160 may include a touch electrode (e.g., a touch electrode TE in FIG. 5). The touch layer 160 may detect a touch from outside and perform a role of transmitting signals to a touch driver.

The component 300 may be disposed under the substrate SUB. The component 300 may be disposed corresponding to the component area CA in a plan view. In an embodiment, for example, a light incident in the component area CA may transmit through the transmission area TA. The pixel (e.g., the pixel PX) may not be disposed in the transmission area TA. Accordingly, a resolution of an image provided from the component area CA may be relatively lower than a resolution of an image provided from the main display area MDA.

In an embodiment, examples of the component 300 may be a camera module, a face recognition sensor module, a pupil recognition sensor module, an acceleration sensor module, a proximity sensor module, an infrared sensor module, and an illuminance sensor module, and/or the like. The camera module may be a module that captures or recognizes images of objects located in front of the display device. The facial recognition sensor module may be a module that detects the user's face. The pupil recognition sensor module may be a module that detects the user's pupils. The acceleration sensor module and the geomagnetic sensor module may be modules that determine movement of the display device. The proximity sensor module and the infrared sensor module may be modules that detect proximity to the front of the display device. The illuminance sensor module may be a module that measures the degree of external brightness.

When the planarization member 200 is not disposed on the first inorganic encapsulation layer 142, a height of an organic encapsulation layer 144 in the component area CA may be relatively lower than a height of an organic encapsulation layer 144 in the main display area MDA by the step portion 142a of the first inorganic encapsulation layer 142.

The display device DD1 according to embodiments of the present disclosure may include the planarization member 200 having a different surface energy than the first inorganic encapsulation layer 142. In addition, the planarization member 200 may be disposed on the first inorganic encapsulation layer 142 to overlap the step portion 142a in a plan view. Accordingly, a height difference of the organic encapsulation layer 144 between the component area CA and the main display area MDA adjacent to the component area CA may be reduced. Accordingly, the organic encapsulation layer 144 may have a substantially flat upper surface over the component area CA and the main display area MDA adjacent to the component area CA through the planarization member 200.

FIG. 5 is a cross-sectional view illustrating another example taken along line I-I′ in FIG. 1.

Hereinafter, descriptions of configurations that overlap with those described with reference to FIG. 3 will be omitted or simplified.

Touch layer 160 may include a first touch insulating layer 162, a touch electrode TE, and a second touch insulating layer 164.

The first touch insulating layer 162 may be disposed on the encapsulation layer 140. In an embodiment, for example, the first touch insulating layer 162 may be disposed on the second inorganic encapsulation layer 146. In addition, the first touch insulating layer 162 may have a step portion 162a in the component area CA.

The first touch insulating layer 162 may include a inorganic insulating material. In an embodiment, for example, the inorganic insulating material may include a silicon nitride, a silicon oxide, a silicon oxynitride, and/or the like. These may be used alone or in a combination with each other. In this specification, the first touch insulating layer 162 may be referred to as an “inorganic layer”.

A planarization member 200′ may be disposed on the first touch insulating layer 162. The planarization member 200′ may cover an upper portion of the first touch insulating layer 162 in the component area CA. In an embodiment, the planarization member 200′ may be disposed to overlap the step portion 162a in a plan view. Accordingly, the planarization member 200′ may compensate a step of the step portion 162a of the first touch insulating layer 162.

The planarization member 200′ may have a surface energy different from a surface energy of the first touch insulating layer 162. In an embodiment, the surface energy of the planarization member 200′ may be lower than a surface energy of the first touch insulating layer 162. Accordingly, an organic material forming the second touch insulating layer 164 may gather in an area where the planarization member 200′ is disposed rather than an area where only the first touch insulating layer 162 is disposed. Therefore, although a step (e.g., the step portion 162a of the first touch insulating layer 162) between the transmission area TA and non-transmission area NTA, the second touch insulating layer 164 may have a substantially flat surface over the component area CA and the main display area MDA.

The touch electrode TE may be disposed on the first touch insulating layer 162. The touch electrode TE may include a metal, an alloy, a metal oxide, a transparent conductive material, and/or the like. In an embodiment, for example, the touch electrode TE may include silver (Ag), an alloy including silver, molybdenum (Mo), an alloy including molybdenum, aluminum (Al), an alloy including aluminum, aluminum nitride (AlN), tungsten (W), tungsten nitride (WN), copper (Cu), nickel (Ni), chromium (Cr), chromium nitride (CrN), titanium (Ti), tantalum (Ta), platinum (Pt), scandium (Sc), indium tin oxide (“ITO”), indium zinc oxide (“IZO”), and/or the like. These may be used alone or in combination with each other.

The second touch insulating layer 164 may be disposed on an upper portion of the first touch insulating layer 162. The second touch insulating layer 164 may cover each of the first touch insulating layer 162, the touch electrode TE, and the planarization member 200′. The second touch insulating layer 164 include an organic material. Like the organic encapsulation layer 144 in FIG. 4, the second touch insulating layer 164 may have a substantially flat upper surface. In this specification, the second touch insulating layer 164 may be referred to as an “organic layer”.

As described with reference to FIGS. 3 and 5, the organic layer may have a substantially flat upper surface over the component area CA and the main display area MDA through the planarization member 200′

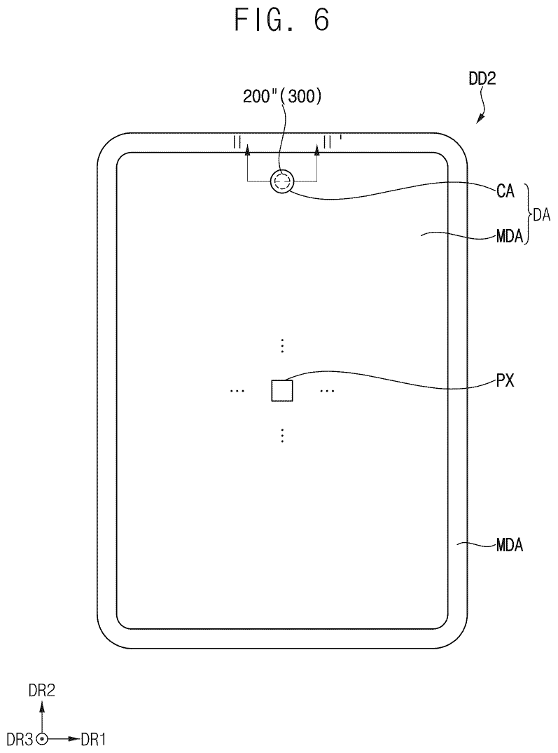

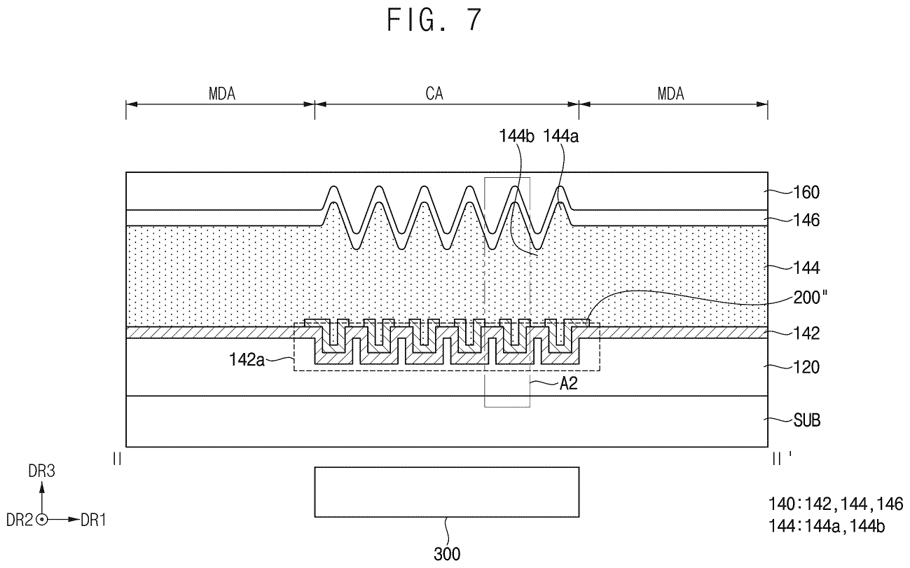

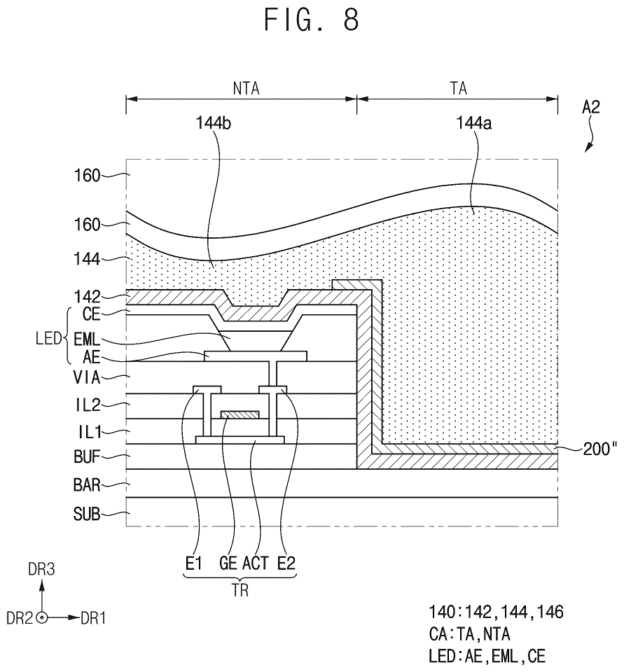

FIG. 6 is a plan view illustrating a display device according to another embodiment of the present disclosure. FIG. 7 is a cross-sectional view illustrating an example taken along line II-II′ in FIG. 6. FIG. 8 is an enlarged plan view illustrating an area A2 in FIG. 7.

Hereinafter, descriptions that overlaps with those described with reference to FIGS. 1, 2, 3, and 4 will be omitted or simplified.

A display device DD2 according to an embodiment of present disclosure may be substantially same as the display device (e.g., the display device DD1 in FIG. 1) excluding a planarization member 200″.

Referring to FIGS. 6, 7, and 8, in the component area CA, the first inorganic encapsulation layer 142 may have the step portion 142a and the planarization member 200″ may be disposed to overlap the step portion 142a in a plan view. In addition, in the component area CA, the planarization member 200″ may cover a portion of the first inorganic encapsulation layer 142. The planarization member 200″ may have a specific pattern and may be disposed on the first inorganic encapsulation layer 142. In an embodiment, for example, the planarization member 200″ may be disposed over a portion of the non-transmission area NTA and the transmission area. Meanwhile, the present disclosure may not be limited to this, and the planarization member 200″ may be only disposed in the transmission area TA in another embodiment.

As described above, a surface energy of the planarization member 200″ may be lower than a surface energy of the first inorganic encapsulation layer 142. Accordingly, portions of the organic encapsulation layer 144 disposed on the planarization member 200″ and located in areas corresponding to a location of the planarization member 200″ in a plan view may protrude into a third direction DR3. That is, the organic encapsulation layer 144 may have a concave-convex structure including a convex portion 144a and a concave portion 144b.

As the planarization member 200″ is disposed corresponding to the transmission area TA in a plan view, the convex portion 144a of the organic encapsulation layer 144 may be formed corresponding to the transmission area TA in a plan view. Accordingly, when an incident light passes through the component area CA, a concentration of the light may be improved. In addition, a characteristic of image quality of the display device DD2 may be further improved.

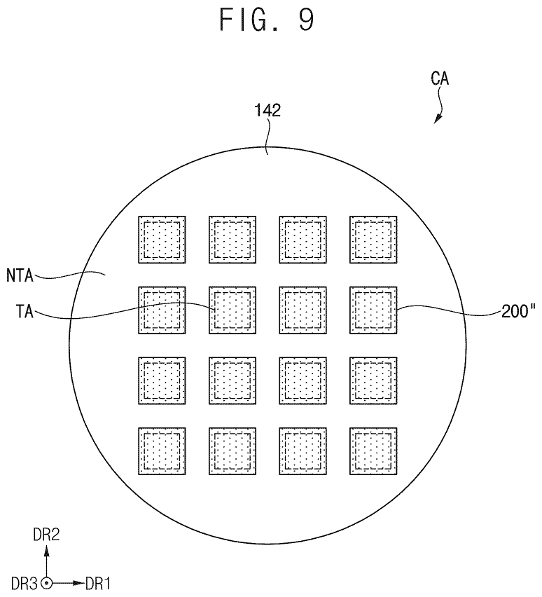

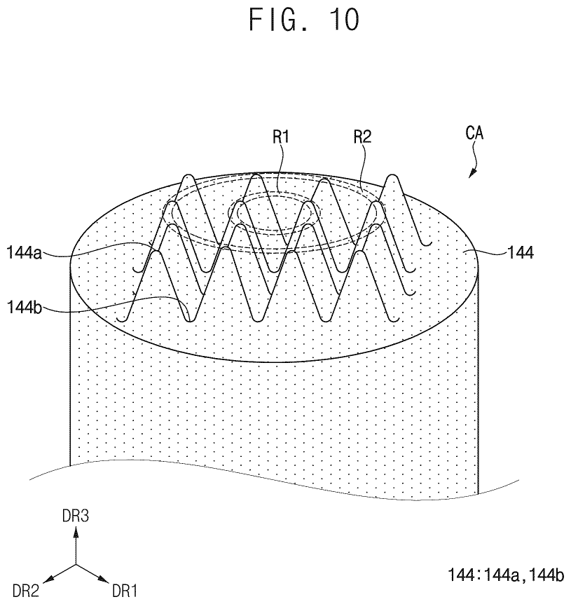

FIG. 9 is a plan view illustrating a component area in FIG. 7. FIG. 10 is a perspective view illustrating an organic layer disposed in a component area.

Referring to FIGS. 9 and 10, the planarization member 200″ may be disposed corresponding to the transmission area TA in a plan view. The planarization member 200″ may have a specific pattern and may disposed in the transmission area TA. In an embodiment, for example, the planarization member 200″ may be arranged repeatedly along the first direction DR1 and the second direction DR2 corresponding to the transmission area TA in a plan view. The planarization member 200″ may be disposed in a portion of the non-transmission area NTA adjacent to the transmission area TA. Meanwhile, the present disclosure may not be limited to this, the planarization member 200″ may be disposed only in the transmission area TA in another embodiment.

As the planarization member 200″ may arranged by having the specific pattern, the convex portion 144a also may arranged by having a specific pattern. In an embodiment, for example, as the planarization member 200″ may be repeatedly arranged along the first direction DR1 and the second direction DR2, the convex portion 144a and the concave portion 144b also may be repeatedly arranged along the first direction DR1 and the second direction.

In response to an arranged shape of the planarization member 200″, an arranged shape of the organic encapsulation layer 144 may be formed. In an embodiment, a plane shape of the convex portion 144a may form first and second imaginary circular rings R1 and R2. The first and second imaginary circular rings R1 and R2 may have the same center and may be spaced apart each other in the first direction DR1 and the second direction DR2. Specifically, the plane shape of the convex portion 144a may be disposed in the first and the second imaginary circular rings R1 and R2. In addition, the concave portion 144b may be disposed between the first imaginary circular ring R1 and the second imaginary circular ring R2. That is, the convex portion 144a and the concave portion 144b may be repeatedly arranged in first direction DR1 and the second direction DR2 from the center.

In an embodiment, repeating plane shapes of the convex portion 144a and the concave portion 144b may be substantially same as or similar to a shape of Fresnel lens. Accordingly, when a light incident from outside, as the organic encapsulation layer 144 may have a substantially similar shape as the Fresnel lens, a concentration of a light transmitted to the component 300 through the transmission area TA may be improved. Therefore, a characteristic of an image quality of the display device DD2 may be effectively improved in the component area CA.

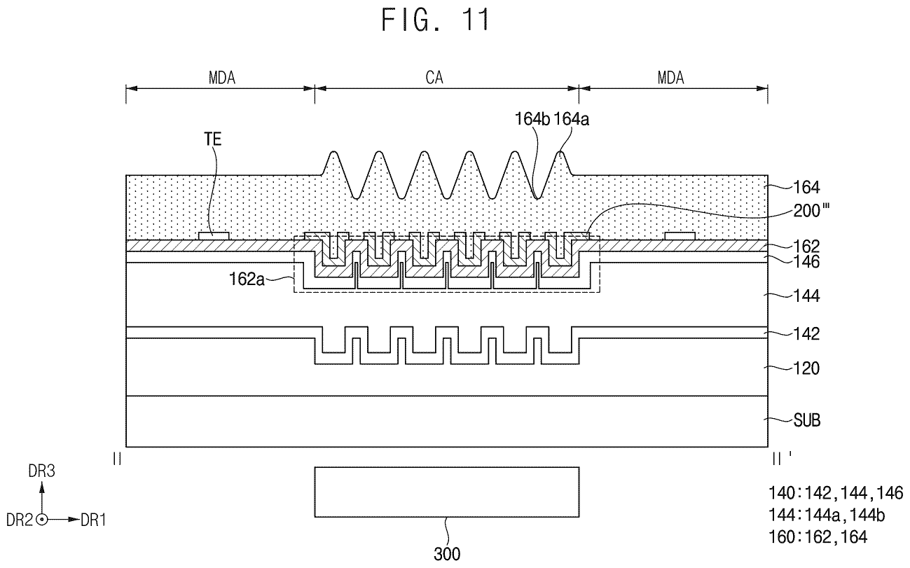

FIG. 11 is a cross-sectional view illustrating another example taken along line II-II′ in FIG. 6.

Hereinafter, descriptions that overlaps with those described in FIGS. 5, 6, and 7 may be omitted or simplified.

The first touch insulating layer 162 may have the step portion 162a in the component area CA. In addition, the planarization member 200′″ may be disposed on the encapsulation layer 140. In an embodiment, for example, the planarization member 200′″ may be disposed on the first touch insulating layer 162. In an embodiment, the planarization member 200′″ may be disposed to overlap the step portion 162a in a plan view.

As the planarization member 200′″ has a specific pattern, the second touch insulating layer 164 may also include the convex portion 164a and the concave portion 164b corresponding to the planarization member 200′″ in a plan view. A plane shape of the convex portion 164a may have a circular ring shape in a plan view, as shown in FIG. 10. In addition, a plane shape of the convex portion 164a and the concave portion 164b may have a substantially same shape as or similar to the shape of the Fresnel lens.

The display device according to the embodiments may be applied to a display device included in a computer, a notebook, a mobile phone, a smartphone, a smart pad, a PMP, a PDA, an MP3 player, or the like.

Although the display device according to the embodiments have been described with reference to the drawings, the illustrated embodiments are examples, and may be modified and changed by a person having ordinary knowledge in the relevant technical field without departing from the technical spirit described in the following claims.

What is claimed is:

1. A display device comprising:
a substrate including a main display area and a component area adjacent to the main display area;
a light emitting element layer disposed in the main display area and the component area on the substrate and including at least one light emitting element;
an inorganic layer disposed on the light emitting element layer;
a planarization member disposed in the component area on the inorganic layer and having a surface energy different from a surface energy of the inorganic layer; and
an organic layer disposed on the inorganic layer and the planarization member.

2. The display device of claim 1, wherein the inorganic layer has a step portion in the component area, and
wherein the planarization member is arranged to overlap the step portion in a plan view.

3. The display device of claim 1, wherein the surface energy of the planarization member is lower than the surface energy of the inorganic layer.

4. The display device of claim 1, wherein the planarization member includes an inorganic material.

5. The display device of claim 1, wherein the component area includes a transmission area, through which an external light passes, and a non-transmission area adjacent to the transmission area.

6. The display device of claim 5, wherein the planarization member is disposed in the transmission area and the non-transmission area in a plan view.

7. The display device of claim 1, wherein the planarization member transmits at least a portion of an incident light.

8. The display device of claim 1, wherein the inorganic layer is an inorganic encapsulation layer, which covers the light emitting element, and
wherein the organic layer is an organic encapsulation layer disposed on the inorganic encapsulation layer.

9. The display device of claim 1, further comprising:
an encapsulation layer disposed between the inorganic layer and the light emitting element layer; and
a touch electrode disposed between the inorganic layer and the organic layer.

10. The display device of claim 1, wherein an upper surface of the organic layer is substantially flat over the component area and at least a portion of the main display area adjacent to the component area.

11. A display device comprising:
a substrate including a main display area and a component area adjacent to the main display area;
a light emitting element layer disposed in the main display area and the component area on the substrate and including at least one light emitting element;
an inorganic layer disposed on the light emitting element layer;
a planarization member disposed in the component area on the inorganic layer and having a surface energy different from a surface energy of the inorganic layer; and
an organic layer disposed on the inorganic layer and the planarization member and including an upper surface with a concave-convex structure including a concave portion and a convex portion.

12. The display device of claim 11, wherein the inorganic layer has a step portion in the component area, and
wherein the planarization member is arranged to overlap the step portion in a plan view.

13. The display device of claim 11, wherein the surface energy of the planarization member is lower than the surface energy of the inorganic layer.

14. The display device of claim 11, wherein the planarization member includes an inorganic material.

15. The display device of claim 11, wherein the convex portion is located to correspond to a location that the planarization member is disposed in a plan view.

16. The display device of claim 11, wherein the planarization member transmits at least a portion of an incident light.

17. The display device of claim 11, wherein the component area includes a transmission area, through which an external light passes, and a non-transmission area adjacent to the transmission area.

18. The display device of claim 17, wherein the planarization member is disposed in the transmission area in a plan view.

19. The display device of claim 11, wherein the inorganic layer is an inorganic encapsulation layer, which covers the light emitting element, and
wherein the organic layer is an organic encapsulation layer disposed on the inorganic encapsulation layer.

20. The display device of claim 11, further comprising:
an encapsulation layer disposed between the inorganic layer and the light emitting element layer; and
a touch electrode disposed between the inorganic layer and the organic layer.
